(19) United States
(12) Patent Application Publication
(10) Pub. No.: US 2019/0297758 A1
(43) Pub. Date: Sep. 26, 2019

(54) ELECTROMAGNETIC SHIELDING CAP, AN ELECTRICAL SYSTEM AND A METHOD FOR FORMING AN ELECTROMAGNETIC SHIELDING CAP

(71) Applicant: Intel IP Corporation, Santa Clara, CA (US)

(72) Inventors: Sonja KOLLER, Regensburg (DE); Saravana MARUTHAMUTHU, Munich (DE); Bernd WAIDHAS, Pettendorf (DE)

(21) Appl. No.: 15/933,402

(22) Filed: Mar. 23, 2018

(51) Int. Cl. H05K 9/00; H05K 1/02; H05K 1/11

(52) U.S. Cl. CPC H05K 9/0028; H05K 1/0233; H05K 2201/10371; H05K 1/115; H05K 9/0084; H05K 1/0298

(57) ABSTRACT

An electromagnetic shielding cap for shielding an electrical circuit on a circuit board includes a frame structure and a lid structure containing a passive electrical element structure. The lid structure is attached to the frame structure and further contains at least one contact interface for connecting the passive electrical element structure to an electrical circuit to be shielded by the electromagnetic shielding cap.

### FIELD

Examples relate to electromagnetic shielding caps, electrical systems, methods for forming electromagnetic shielding caps and methods for forming electrical systems.

### BACKGROUND

An electrical circuit on a circuit board of a mobile device may contain parts or components that can be disturbed by external electromagnetic fields due to interference effects. Other parts or components of the electrical circuit or of another electrical circuit may emit an electromagnetic field possibly interfering with other electrical circuits or devices in vicinity of the electrical circuit emitting the electromagnetic field. Radio frequency and power management circuits in mobile devices may comprise passive electrical elements sensitive to electromagnetic interference. Interfering electromagnetic fields may lead to malfunction of an electronic device.

For providing a reliable functionality of an electrical device, electromagnetic shielding might be necessary to limit electromagnetic interference. However, providing electromagnetic shielding may require space in an electrical device comprising the electrical circuit. Available space may be limited within the electrical device due to a high component integration density of the electrical device. Especially in mobile devices, space for providing electromagnetic shielding for electrical circuits may be limited. There may be a need for improved concepts for providing electromagnetic shielding of electrical circuits.

### BRIEF DESCRIPTION OF THE FIGURES

Some examples of apparatuses and/or methods will be described in the following by way of example only, and with reference to the accompanying figures, in which

FIG. 1 shows a schematic illustration of an electromagnetic shielding cap;

FIG. 2 shows a schematic illustration of an electrical system;

FIG. 3 shows an enlarged section of a schematic illustration of a lid structure of an electrical system;

FIG. 4 shows a schematic illustration of an electrical system with a schematic 3D illustration of an example of a passive electrical element structure;

FIG. 5 shows a schematic illustration of a coil embedded in a lid structure;

FIG. 6 shows a diagram comprising simulated quality factors of coils;

FIG. 7 shows a schematic illustration of a cross section of an electrical system;

FIG. 8 shows a flow chart of a method for forming an electromagnetic shielding cap;

FIG. 9 shows a flow chart of a method for forming an electrical system; and

FIG. 10 shows a schematic illustration of a method for forming an electrical system.

### DETAILED DESCRIPTION

Various examples will now be described more fully with reference to the accompanying drawings in which some examples are illustrated. In the figures, the thicknesses of lines, layers and/or regions may be exaggerated for clarity.

Accordingly, while further examples are capable of various modifications and alternative forms, some particular examples thereof are shown in the figures and will subsequently be described in detail. However, this detailed description does not limit further examples to the particular forms described. Further examples may cover all modifications, equivalents, and alternatives falling within the scope of the disclosure. Like numbers refer to like or similar elements throughout the description of the figures, which may be implemented identically or in modified form when compared to one another while providing for the same or a similar functionality.

It will be understood that when an element is referred to as being “connected” or “coupled” to another element, the elements may be directly connected or coupled or via one or more intervening elements. If two elements A and B are combined using an “or”, this is to be understood to disclose all possible combinations, i.e. only A, only B as well as A and B. An alternative wording for the same combinations is “at least one of A and B”. The same applies for combinations of more than 2 Elements.

The terminology used herein for the purpose of describing particular examples is not intended to be limiting for further examples. Whenever a singular form such as “a,” “an” and “the” is used and using only a single element is neither explicitly or implicitly defined as being mandatory, further examples may also use plural elements to implement the same functionality. Likewise, when a functionality is subsequently described as being implemented using multiple elements, further examples may implement the same functionality using a single element or processing entity. It will be further understood that the terms “comprises,” “comprising,” “includes” and/or “including,” when used, specify the presence of the stated features, integers, steps, operations, processes, acts, elements and/or components, but do not preclude the presence or addition of one or more other features, integers, steps, operations, processes, acts, elements, components and/or any group thereof.

Unless otherwise defined, all terms (including technical and scientific terms) are used herein in their ordinary meaning of the art to which the examples belong.

In electrical devices dealing with electrical circuits including passives, e.g. passive electrical elements, in particular RF (radio frequency), mm wave and power management solutions, electromagnetic shielding of the electrical circuit may be required whereas space for providing electrical elements or components for electromagnetic shielding may be limited or there may be a desire to further decrease a volume or a size of the electrical device. It may be desired to reduce an area of an electrical circuit on a circuit board in an electrical device while providing electromagnetic shielding for the electrical circuit. Examples of electromagnetic shielding caps are provided in the following.

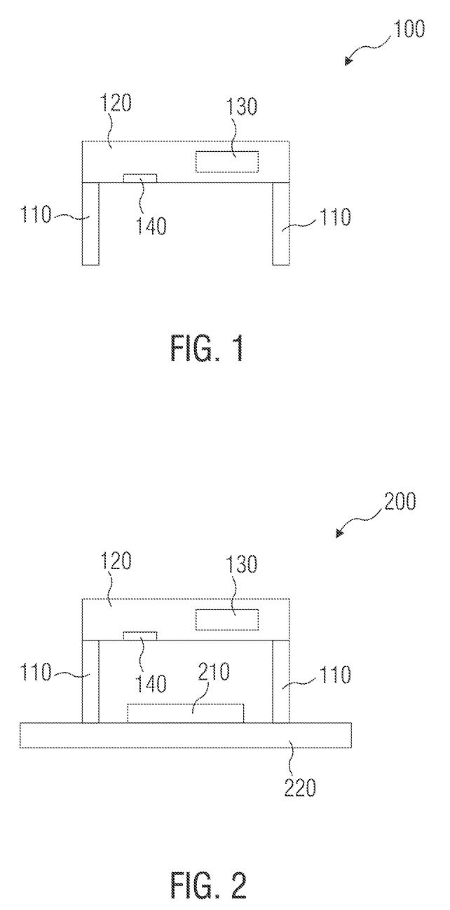

FIG. 1 shows a schematic illustration of an electromagnetic shielding cap 100 for shielding an electrical circuit on a circuit board. The electromagnetic shielding cap 100 may comprise a frame structure 110 and a lid structure 120. The lid structure 120 may comprise a passive electrical element structure 130. The lid structure 120 may be attached to the frame structure 110. The lid structure 120 may comprise at least one contact interface 140 for connecting the passive electrical element structure 130 to an electrical circuit to be shielded by the electromagnetic shielding cap 100.

The electromagnetic shielding cap 100 may be configured to provide shielding against electromagnetic radiation and may comprise a passive electrical element structure 130 connectable to an electrical circuit. The electrical circuit may be the electrical circuit to be shielded by the electromagnetic shielding cap 100. For example, the passive electrical element structure 130 can be configured or designed to be a part or a component of the electrical circuit to be shielded by the electromagnetic shielding cap 100. By shielding an electrical circuit with the electromagnetic shielding cap 100 instead of another electromagnetic shielding can (e.g. a shielding can exclusively made of a sheet metal) it may be possible to integrate a part or an element (e.g. passive component) of the electrical circuit into the electromagnetic shielding cap 100. Using the electromagnetic shielding cap may result in providing electromagnetic shielding of an electrical circuit while reducing an area needed for the electrical circuit on the circuit board due to the integration of at least one passive component from the circuit board into the lid structure. In this way, the size and/or costs of an electrical device may be reduced.

For example, by integrating a passive electrical element of the electrical circuit into the electromagnetic shielding cap, an area needed for the electrical circuit on the circuit board may be reduced by the size of an area of the passive electrical element integrated into the electromagnetic shielding cap. Accordingly, a size of the electromagnetic shielding cap may be reduced compared to other shielding cans. In some examples a height of the electromagnetic shielding cap 100 might not exceed a height of another electromagnetic shielding can, and by using the electromagnetic shielding cap 100 a volume or a space needed for the electromagnetically shielded electrical circuit in an electrical device may be reduced. By providing the electromagnetic shielding cap 100, an area of the electrical circuit may be smaller than an electrical circuit shielded by another electromagnetic shielding can without a deterioration of electromagnetic shielding compared to electromagnetic shielding provided by using other electromagnetic shielding cans.

Providing a passive electrical element of an electrical circuit in the electromagnetic shielding cap 100 as passive electrical element structure 130 may lead to a higher quality factor of the passive electrical element. The passive electrical element structure 130 in the lid structure 120 may be elevated from a substrate material or material of a circuit board of the electrical circuit due to the frame structure 110 between the lid structure and the substrate material. The passive electrical element structure 130 may be located further away from the substrate than a passive electrical element located on the circuit board. By providing a larger distance from the passive electrical element to the circuit board, loss effects of the passive electrical element caused by the substrate material of the circuit board may be reduced and a quality factor of the passive electrical element may be improved.

The lid structure 120 may comprise at least one passive electrical element structure 130. The passive electrical element structure may be embedded in the lid structure and/or attached to the lid structure and/or formed on the lid structure. The passive electrical element structure may be implemented by structured electrically conductive material of the lid structure 120 embedded by electrically insulating material of the lid structure 120. The at least one passive electrical element structure 130 can comprise a functionality of one or more passive components. A plurality of functionalities of passive electrical elements could be provided by the passive electrical element structure 130 possibly leading to a further reduced size of the electrical circuit or electrical device. The passive electrical element structure may substitute a plurality of passive components of the electrical circuit on the circuit board. The electromagnetic shielding cap 100 may be called a multifunction electromagnetic shielding cap providing electromagnetic shielding for an electrical circuit and at least one passive electrical component for an electrical circuit.

The passive electrical element structure 130 may be embedded in the lid structure 120 by being completely covered by an insulating material of the lid structure 120. Alternatively, the passive electrical element structure 130 may be embedded in the lid structure 120 by being partly covered by insulating material of the lid structure 120, while a part of the passive electrical element structure 130 may be uncovered. For example, the passive electrical element structure 130 may be formed on or attached to a surface of a carrier layer of the lid structure 120, e.g. the surface of the lid structure 120 facing towards the frame structure 110. For example, the lid structure 120 may comprise an electrically insulating carrier layer with electrically conductive traces on the electrically insulating carrier layer forming the passive electrical element structure 130.

The at least one passive electrical element structure 130 may be connectable to at least one electrical circuit via the at least one contact interface 140. For connecting a passive electrical element structure 130 with two or more electrical pins or terminals, the lid structure 120 may provide two or more contact interfaces 140, respectively. In other words, for every electrical pin of the passive electrical element structure 130 a separate contact interface 140 may be provided. For example, a connection from the passive electrical element structure 130 to the electrical circuit to be shielded or covered can be established via an electrical connector connectable to the contact interface 140.

For example, the contact interface 140 may be electrically connected to the passive electrical element structure 130, e.g. by an electrically conductive trace inside the lid structure 120 or at a surface of the lid structure 120. For example, the passive electrical element structure 130 may reach to the contact interface 140. The contact interface 140 may comprise a contact pad (e.g. solder pad) and/or a plug and/or a socket for a connector each respectively configured to enable a connection for an electrical connector or an electrical connection to a contact interface of an electrical circuit to be shielded.

For example, the passive electrical element structure 130 of the lid structure 120 may comprise or is at least one of a resistor, a capacitor, a coil and an antenna. In other words, the passive electrical element structure 130 may be a single one or a combination of the mentioned passive electrical elements. The lid structure 120 may comprise a plurality of passive electrical elements. For example, a first element of the passive electrical element structure 130 like a coil may be located on a side of the lid structure 120 facing towards the frame structure 110, and a second element of the passive electrical element structure 130 like an antenna may be located on a side of the lid structure 120 opposite to the frame structure 110.

For example, the passive electrical element structure 130 of the lid structure may be implemented in a single layer of the lid structure (e.g. single turn coil) or may comprise an electrical multilayer structure (e.g. a multilayer coil or a multilayer capacitor). A multilayer structure may further reduce an area needed to provide a functionality of the passive electrical element structure 130. For example, the lid structure may comprise a plurality of lateral wiring layers and a plurality of vertical wiring layers. A lateral wiring layer (e.g. metal layer of a layer stack) may be a layer for implementing lateral electrical connections between vertical electrical connections (vias) connecting lateral wiring layers. A vertical wiring layer (e.g. via layer of a layer stack) may be a layer for implementing vertical electrical connections (vias) between lateral wiring layers. For example, the passive electrical element structure 130 may be implemented in one or more of the lateral and vertical wiring layers of the lid structure 120. The electrical multilayer structure may enable to provide a more complex passive electrical element structure 130.

Optionally, a lid structure may comprise an electrically conductive shielding structure insulated from the passive electrical element structure. For example, one of a plurality of lateral wiring layers may be used to implement an electrically conductive shielding structure of the lid structure 120. The passive electrical element structure may be arranged in one or more layers of the lid structure located closer to the frame structure than one or more layers of the lid structure comprising the electrically conductive shielding structure. The electrically conductive shielding structure may be an electrically conductive layer extending over more than 70% (or more than 90%) of a lateral area of the lid structure. For example, a layer or continuous layer of electrically insulating material may completely separate or insulate the layer of the electrically conductive shielding structure from the passive electrical element structure 130. Alternatively and/or additionally, a passive electrical element structure may be arranged in one or more layers of the lid structure located farer from the frame structure than one or more layers of the lid structure comprising the electrically conductive shielding structure.

For example, the electrically conductive shielding structure can be on a side of the lid structure opposite to the frame structure, for example on a top side of the lid structure 120. For example, the electrically conductive shielding structure may be enclosed by electrically insulating material except for an electrical connection to a contact interface of the lid structure 120. Alternatively, the electrically conductive shielding structure may form a surface of the lid structure 120, for example the surface of the lid structure 120 opposite to the frame structure 110. For example, the electrically conductive shielding structure is configured to attenuate an electromagnetic field strength of an electromagnetic field approaching from a first side of the electrically conductive shielding structure on a second side of the electrically conductive shielding structure and may improve the electromagnetic shielding of the electromagnetic shielding cap 100. Positioning the electrically conductive shielding structure on a side opposite to the frame structure may provide shielding of electromagnetic radiation emitted by the passive electrical element structure 130 outside the electromagnetic shielding cap 100.

For example, the lid structure 120 may comprise an electrically conductive shielding structure electrically connected to the frame structure. For example, the electrically conductive shielding structure may be electrically connected to the frame structure 110 via a single electrically conductive element or wire or trace. Alternatively, the electrically conductive shielding structure may be electrically connected to the frame structure 110 via an electrical connection at a contact region between the lid structure 120 and the frame structure 110. The contact region may be at least a part of a region where the lid structure 120 is attached to the frame structure 110. For example, the electrically conductive shielding structure may be electrically connected to the frame structure 110 at the complete contact region, e.g. if the lid structure 120 is soldered to the frame structure 110. The frame structure 110 may comprise at least one electrically conductive trace connected to the electrically conductive shielding structure. For example, the electrically conductive trace may reach from a side of the frame structure 110 facing to the lid structure 120 to a side of the frame structure 110 opposite to the lid structure 120 and the electrically conductive trace may be connectable to a circuit board carrying the electrical circuit to be shielded or covered by the electromagnetic shielding cap. For example, the electrically conductive shielding structure may comprise a same material as the passive electrical element structure 130.

Optionally, a contact interface 140 of the lid structure 120 may be located on a side of the lid structure facing towards the frame structure. For example the contact interface 140 is located outside a region where the lid structure 120 is attached to the frame structure 110. For example, the contact interface 140 may be located in a center region of the lid structure 120 within the frame structure. For example, the passive electrical element structure 130 may comprise two electrical terminals and a first contact interface 140 may be located closer to a first edge of the lid structure 120 than a second contact interface 140 while the second contact interface 140 may be located closer to a second edge of the lid structure 120 than the first contact interface 140. In some examples, all contact interfaces 140 may be located next to each other within a same region of the lid structure 120, such that a respective electrical line of a plurality of electrical lines of a connector may be connected to each contact interface 140. Positioning the contact interface on said side may facilitate a connection of the passive electrical element structure to the electrical circuit on the circuit board.

Optionally, an electrical connector may be connected to the contact interface. The electrical connector may provide a connection from the contact interface 140 directly to the electrical circuit or alternatively to the circuit board and via the circuit board to the electrical circuit. A connector may be a wire with a cable plugged into the contact interface 140 and the electrical connector may comprise a plug or a connector on a side opposite to the at least one contact interface 140. Alternatively, a side of the electrical connector opposite to the at least one contact interface 140 may comprise electrical lines connectable to contact interfaces of the electrical circuit or the circuit board e.g. by bonding and/or soldering. For example, the side of the electrical connector opposite to the contact interface 140 may be designed according to a contact interface of the electrical circuit to be shielded. The passive electrical element structure 130 may have two electrical pins and the electrical connector may comprise two electrical lines, each for one of the pins. For example, the electrical connector may be an electrical wire, e.g. flexible or rigid, comprising a plurality of electrical lines. The lid structure 120 may comprise an electrically conductive shielding structure and a contact interface 140 or an additional contact interface 140 may be provided to connect the electrically conductive shielding structure via the electrical connector to the electrical circuit or the circuit board. The electrical connector may be soldered or glued with an electrical conductive glue to the at least one contact interface 140.

Optionally, a height of the electrical connector may differ from a height of the frame structure by less than 20% (or less than 10%, or less than 5%) of the height of the frame structure. For example, the height of the electrical connector is smaller than the height of the frame structure 110. For example, a difference in the height between the frame structure and the electrical connector may be compensated by solder, electrically conductive glue or another connection used to connect the electrical connector to the contact interface 140. In other words, the height of the electrical connector may be similar to a height of the frame structure, such that a bottom side of the electrical connector and a bottom side of the frame structure 110 may be positioned within an even plane and may be connectable to a plane circuit board, wherein the bottom side is a side opposite to the lid structure 120.

For example the electrical connector may be rigid. For example, a form of a rigid electrical connector cannot be reversibly changed, e.g. when trying to change the form, the rigid electrical connector might break. According to other examples, the electrical connector may be flexible, e.g. the flexible electrical connector can be an electrical wire comprising one or more electrical lines. If the electrical connector is flexible, its height may be larger than the height of the frame structure 110 as the electrical connector can adapt its form.

Optionally, the contact interface 140 of the lid structure 120 may be positioned in a contact region of the lid structure. The contact region may be a region of the lid structure in contact with the frame structure and the frame structure may comprise at least one conductive trace connected to the contact interface of the lid structure and extending from the contact region to a side of the frame structure opposite to the lid structure. The passive electrical element structure 130 may comprise two electrical pins, the lid structure 120 may comprise two contact interfaces 140 and the frame structure 110 may comprise two conductive traces configured to connect the contact interfaces 140 with a circuit board comprising an electrical circuit to be shielded. In other words, in some examples an electrical connector may be integrated into the frame structure 110 or attached to the frame structure. For example, an electrical connector integrated in the frame structure 110 may substitute an electrical connector, e.g. an electrical wire, within a cavity of the electromagnetic shielding cap 100. For example, conductive traces of the frame structure 110 may be electrically insulated from other conductive parts of the frame structure 110, e.g. conductive parts connected to an electrically conductive shielding structure of the lid structure 120. For example, conductive traces may be provided on an insulating layer attached to a conductive layer of the frame structure 110.

For example, the lid structure may be soldered, glued, clamped, screwed or connected by a pin header to the frame structure. A solder material of a soldered lid structure 120 may provide an electrical connection between the lid structure 120 and the frame structure 110. A glued connection can comprise electrically conductive glue or electrically insulating glue.

For example, the lid structure 120 may be soldered at one point to the frame structure 110 or at a plurality of points.

Optionally, an anisotropic conductive film may be located between the frame structure and the lid structure. An anisotropic conductive film may be an adhesive interconnect system comprising electrically conductive particles for providing an electrical connection between two elements, e.g. between two electrically conductive surfaces. Instead of an anisotropic conductive film, in some examples an anisotropic conductive paste may be located between the frame structure 110 and the lid structure 120. For example, the anisotropic conductive film reaches continuously around the frame structure 110 between the frame structure 110 and the lid structure 120. The anisotropic conductive film can attach the lid structure 120 to the frame structure 110 and provide electrical connection between the lid structure 120 and the frame structure 110, e.g. at locations between a contact interface 140 and an electrical trace of the frame structure 110 or between an electrically conductive shielding structure of the lid structure 120 and a conductive part of the frame structure 110.

For example, at least a part of the passive electrical element structure 130 of the lid structure 120 may comprise at least one of copper, gold, silver, aluminum and/or an alloy of copper, gold, silver, nickel, tin and/or aluminum. For example, the passive electrical element structure comprises one or more copper traces (e.g. of a coil) and/copper plates (e.g. of a capacitor). For example, the contact interface 140 may comprise the same material as the passive electrical element structure 130. Alternatively, the contact interface 140 may comprise an electrically conductive material different from a material of the passive electrical element structure 130, e.g. one of copper, gold, silver, aluminum, nickel, tin and/or an alloy.

For example, the lid structure may comprise electrically insulating material embedding the passive electrical element structure. The electrically insulating material may be at least one of mold, molding compound, epoxy fiberglass, epoxy fiberglass paper composite, resin, polyester fiberglass, polyimide fiberglass and teflon fiberglass. For example, the electrically insulating material may be a material used for housing electrical components, packaging electrical components or used as substrate material of printed circuit boards (PCBs). For example, the electrically insulating material may separate electrically conductive parts of the passive electrical element structure 130 to provide specific passive electrical elements.

For example, the electrically insulating material may separate different layers of a plurality of layers of the passive electrical element structure 130. The electrically insulating material and the passive electrical element structure 130 may form a multilayer board. For example, the electrically insulating material may provide a base plate of the lid structure 120 and the passive electrical element structure 130 may be attached to the base plate. For example, the passive electrical element structure 130 may be covered by the electrically insulating material, e.g. by molding compound. The passive electrical element structure 130 may be connectable via the contact interface 140 at a surface of the lid structure 120. The contact interface 140 might be uncovered by the electrically insulating material. The lid structure 120 may comprise a plurality of different electrically insulating materials.

Optionally, the frame structure 110 may be electrically conductive. For example, the frame structure 110 may be made of a metal sheet or a metal and be completely electrically conductive. Alternatively, the frame structure 110 may comprise an electrically conductive structure, e.g. an electrically conductive layer at an outside of the frame structure 110 facing away from a cavity of the electromagnetic shielding cap. For example, an outside portion of the frame structure 110 is electrically conductive and an inside portion of the frame structure 110 is electrically insulating. If for example the lid structure 120 comprises an electrically conductive shielding structure, the electrically conductive shielding structure can be connected to the electrically conductive frame structure 110 or an electrically conductive part of the frame structure 110. For example, an electromagnetic shielding provided by the electromagnetic shielding cap 100 may be improved due to a higher attenuation of electromagnetic radiation by the electrically conductive shielding structure and the frame structure 110.

Optionally, a height of the frame structure may be smaller than 5 mm (or smaller than 3 mm, smaller than 1 mm). Alternatively or additionally, the height of the frame structure 110 may be larger than 0.1 mm, larger than 0.3 mm, or larger than 0.5 mm. For example, the height of the frame structure 110 is smaller than 1 mm and/or larger than 0.2 mm.

Optionally, a side length of a longest side of the lid structure 120 and/or the frame structure 110 may be smaller than 5 cm (or smaller than 4 cm, smaller than 3 cm, or smaller than 2 cm). Alternatively or additionally, a side length of the longest side of the lid structure 120 may be larger than 0.2 cm, larger than 1 cm or larger than 2 cm. Accordingly, a longest lateral side length of the frame structure 110 may be smaller than 20 cm (or smaller than 10 cm, or smaller than 5 cm) and/or larger than 0.2 cm (or larger than 1 cm or larger than 2 cm).

The frame structure 110 of the electromagnetic shielding cap 100 may comprise a plurality of wall elements. For example, the wall elements may be connected to each other and enclose a hole open at two opposite sides of the frame structure 110. A height of the frame structure may be a distance between the two opened sides. For example, the frame structure 110 may comprise four wall elements connected to each other respectively in a 90° angle. For example, the frame structure 110 may be square-shaped or rectangular-shaped.

For example, the frame structure 110 may comprise or consist of metal or an electrically conductive material and/or the frame structure 110 may comprise an insulating material, e.g. a plastic material or a synthetic material. The material of the frame structure may be continuously provided in walls of the frame structure.

The lid structure 120 attached to the frame structure 110 may have a shape of a base area of the frame structure 110, wherein the base area may be a side of the frame structure 110 horizontal to a wall element of the frame structure 110 or the base area can be one open side of the frame structure 110. For example, the attached lid structure 120 can cover one of the open sides of the frame structure 110. In other words, the lid structure 120 may be formed to cover one open side of the frame structure 110 at least partly or completely. The lid structure 120 attached to the frame structure 110 together with the frame structure 110 may form a cap structure or can structure opened at one side. For example, the electromagnetic shielding cap 100 may be an empty cube or a cube comprising a cavity with one sidewall missing. For example, an electrical circuit to be covered by the electromagnetic shielding cap 100 can be positioned into a cavity of the electromagnetic shielding cap 100.

For example, the electromagnetic shielding cap 100 may reduce an electromagnetic field strength outside and/or inside the electromagnetic shielding cap 100 by more than 50%, more than 70%, more than 90% or more than 95% and/or less than 99.9% or less than 97% of an electromagnetic field strength inside or outside the electromagnetic shielding cap 100. An electromagnetic field inside the electromagnetic shielding cap may be caused by an electrical circuit inside the electromagnetic shielding cap 100 emitting an electromagnetic field. For example, electromagnetic shielding may be provided for meeting electromagnetic compatibility requirements of an electrical device comprising an electrical circuit emitting an electromagnetic field or for avoiding disturbance due to electromagnetic interference inside an electrical device comprising the electromagnetic field emitting electrical circuit. For example electromagnetic shielding may prevent an electromagnetic field impinging at the electromagnetic shielding cap 100 from outside from interfering with an electrical circuit inside the electromagnetic shielding cap 100.

An electromagnetic shielding cap 100 may be provided in an electrical system, e.g. on an electrical circuit board and/or in an electrical device. Examples of an electrical system are provided in the following.

FIG. 2 shows a schematic illustration of an electrical system 200. The electrical system 200 comprises an electromagnetic shielding cap 100 located over an electrical circuit 210 on a circuit board 220. The electrical circuit 210 may be surrounded by the frame structure 110 and covered by the lid structure 120. For example, the complete electrical circuit or at least parts of it may be shielded or covered by the electromagnetic shielding cap 100.

For example, the passive electrical element structure 130 may be a passive electrical element of the electrical circuit 210, e.g. a coil and/or a capacitor and/or a resistor connected to the electrical circuit 210. The passive electrical element structure 130 may be a passive electrical element of an electrical circuit on the circuit board 220 positioned outside the electromagnetic shielding cap 100. The passive electrical element structure 130 may be emitting an electromagnetic field. For example, an electromagnetic field strength within the electromagnetic shielding cap 100 may have a first value and an electromagnetic field strength outside the electromagnetic shielding cap 100 may have a second value, the second value smaller than the first value, e.g. the second value less than 90%, less than 50%, less than 30% or less than 10% of the first value, due to electromagnetic shielding provided by the electromagnetic shielding cap 100.

For example, the frame structure 110 may be soldered, glued, clamped, screwed or connected by a pin header to the circuit board 220. For example, a connection between the frame structure 110 and the circuit board 220 may be electrically conductive.

Optionally, the electrical system 200 may comprise an electrical connector providing an electrical connection between the contact interface 140 of the lid structure and the electrical circuit 210 on the circuit board 220. For example, the electrical connector may be an electrical wire reaching from the at least one contact interface 140 to a respective contact interface of the electrical circuit 210 or the circuit board 220. For example, the electrical connector may provide a connection from the passive electrical element structure 130 to the electrical circuit 210 and optionally a separated connection from an electrically conductive shielding structure of the lid structure 120 to a ground terminal, e.g. a ground terminal of the circuit board 220. For example, the electrical connector may be located within a cavity of the electromagnetic shielding cap 100, e.g. between walls of the frame structure and between the lid structure and the circuit board.

For example, the passive electrical element structure 130 may be partly connected to the electrical circuit shielded by the electromagnetic shielding cap and partly connected to some other electrical circuit on the circuit board by at least one electrical connector. For example, two parts of the passive electrical element structure 130 may be located on respective opposite sides of the lid structure with respective contact interfaces 140 on each side. For example, a part inside the cavity might be connected to the electrical circuit 210 covered by the electromagnetic shielding cap 100 and a part on top of the lid structure may be connected to an electrical circuit outside the electromagnetic shielding cap 100.

Optionally, the electrical system 200 may comprise a frame structure electrically connected to a reference voltage terminal of the circuit board. The frame structure 110 may be electrically conductive and clamped to the circuit board 220 by electrically conductive clamps.

The clamps may be electrically connected to the reference voltage terminal. The reference voltage terminal may be a terminal providing a ground potential of the electrical circuit 210. For example, the frame structure 110 may be grounded. A result may be a higher electromagnetic shielding effect of the frame structure 110 and a higher electromagnetic shielding effect of the electromagnetic shielding cap 100 of the electrical system 200.

Optionally, the electrical circuit 210 on the circuit board 220 may be at least one of a transmitter circuit, a receiver circuit, a transceiver circuit and a voltage converter circuit. For example the circuit board 220 may be provided in a mobile device. For example, the mobile device may require a voltage converter circuit. The voltage converter circuit may emit an electromagnetic field potentially interfering with other components outside and/or inside the electrical circuit 210. The electrical circuit 210 may show a reduced size due to integration of at least one passive electrical element into the electromagnetic shielding cap 100 compared to providing all elements side by side on the circuit board while at the same time the electromagnetic shielding cap 100 may prevent potentially interfering electromagnetic radiation from leaving and/or entering the electromagnetic shielding cap 100.

In an example, the electrical circuit on the circuit board may be a DC-DC converter circuit wherein the passive electrical element structure of the lid structure is a coil for the DC-DC converter circuit. Integrating a coil of an electrical circuit 210 into the electromagnetic shielding cap 100 may result in a reduced size of a base area of the electrical circuit 210 as a coil may be a relatively large passive component.

Optionally, the electrical circuit on the circuit board may be a semiconductor circuit. For example, a contact interface for connecting the electrical connector from the contact interface 140 may be a bond pad. For example, due to the integration of all passive electrical elements of the electrical circuit 210 into the passive electrical element structure 130 of the electromagnetic shielding cap 100, the electrical circuit 210 on the circuit board 220 may require exclusively semiconductor elements for providing its functionality.

More details and aspects are mentioned in connection with the embodiments described above or below. The embodiments shown in FIG. 2 may comprise one or more optional additional features corresponding to one or more aspects mentioned in connection with the proposed concept or one or more embodiments described above or below (e.g. FIGS. 1 and 3 to 10).

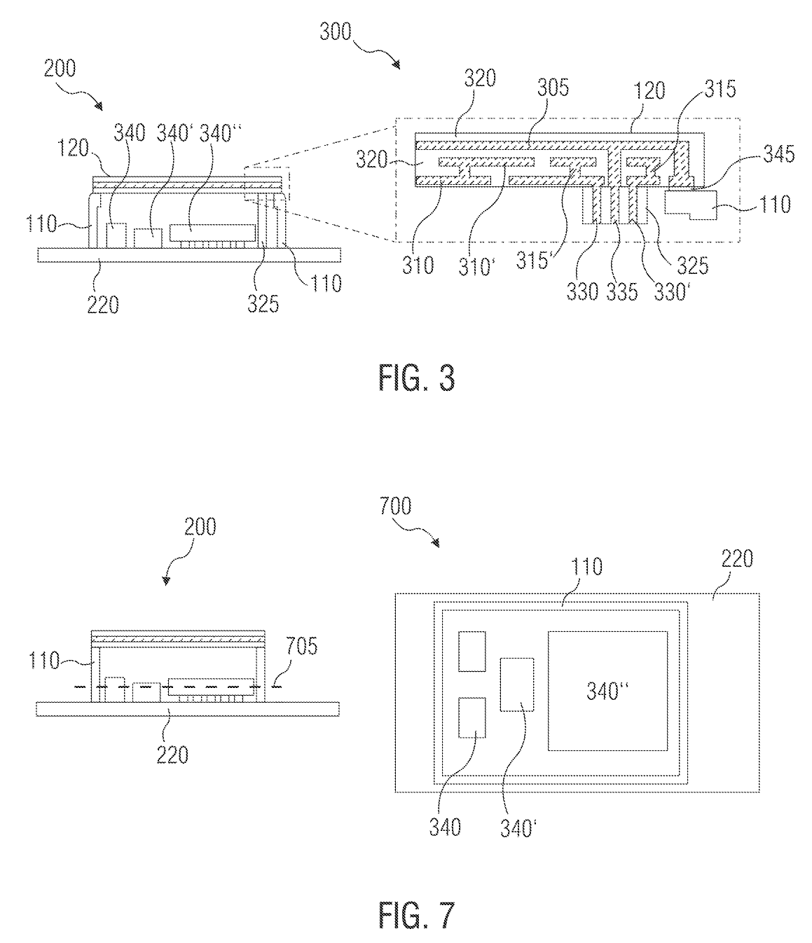

FIG. 3 shows an enlarged section 300 of a schematic illustration of a lid structure 120 of an electrical system 200. The lid structure 120 comprises multiple conductive layers, e.g. horizontal layers, wherein a first layer 305 forms an electrically conductive shielding structure of the lid structure 120 and a second and a third layer 310, 310′ form the passive electrical element structure 130, e.g. a coil. The second and third layer 310, 310′ may be connected by vertical wires 315, 315′. The conductive layers 305, 310, 310′ are insulated by an insulating material 320, e.g. mold compound. An electrical connector 325 is connected to the lid structure 120 and to the circuit board 220. At least a part of the connector 325 provides a connection of the passive electrical element structure 130 to the electrical circuit 210, comprising components 340, 340′ and/or 340″. Therefore, electrical lines 330, 330′ are provided to electrically connect the passive electrical element structure 130 comprising the layers 310, 310′ to the electrical circuit 210. Another electrical line 335 of the electrical connector 325 is configured to connect the layer 305 building the electrically conductive shielding structure of the lid structure 120 to the circuit board 220, e.g. to a ground terminal. In the example of FIG. 3 the lid structure 120 may be soldered to the frame structure 110 by solder 345. Solder 345 e.g. attaches the lid structure 120 to the frame structure 110 and may establish an electrical connection at the same time. For example, the frame structure 110 is electrically conductive and connected to a ground terminal such that as a consequence also lid structure 120 may be electrically connected to the ground terminal.

More details and aspects are mentioned in connection with the embodiments described above or below. The embodiments shown in FIG. 3 may comprise one or more optional additional features corresponding to one or more aspects mentioned in connection with the proposed concept or one or more embodiments described above or below (e.g. FIGS. 1, 2 and 4 to 10).

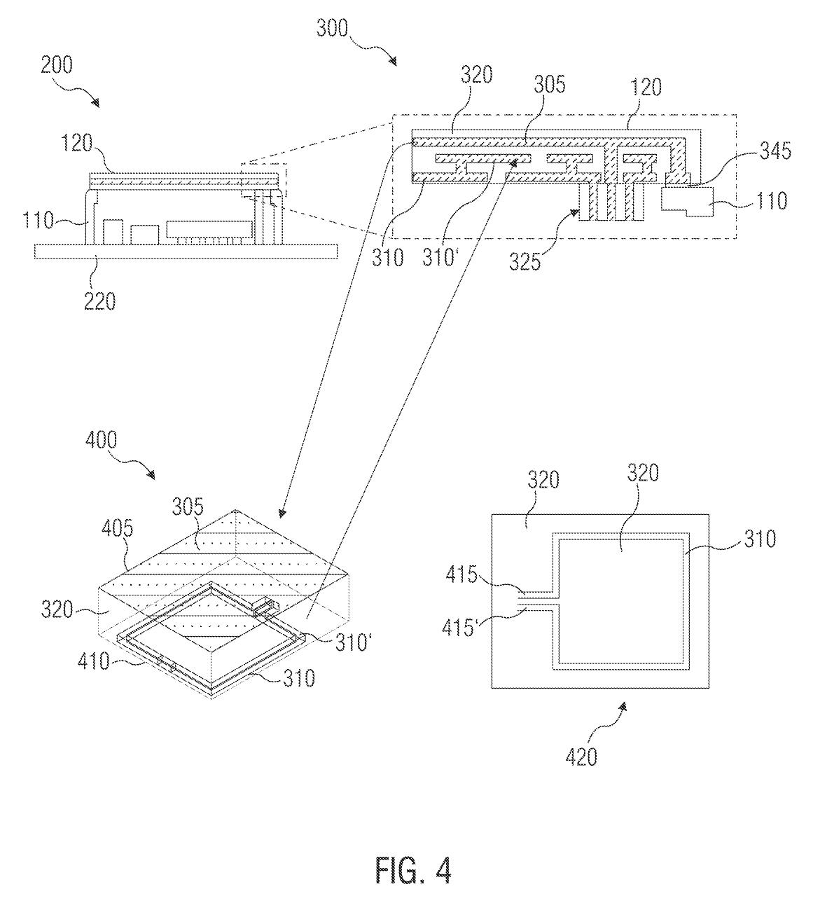

FIG. 4 shows a schematic illustration of an electrical system, e.g. the system 200, with a schematic 3D illustration 400 of an example of a passive electrical element structure. The 3D illustration 400 shows an exemplary lid structure 120 with a layer 305, e.g. an electrically conductive shielding structure, on a side of the lid structure 120 opposite to the frame structure 110. The exemplary lid structure 120 further comprises a passive electrical element structure 130, provided by at least one of the layers 310, 310′ on a side of the lid structure 120 facing towards the frame structure 110, e.g. a bottom side of the lid structure 120. In a bottom view 420 of the lid structure 120 the layer 310 of the passive electrical element structure 130 is shown, covering the layer 310′. The layers 310, 310′ are structured by the insulating material 320, e.g. mold compound. E.g. the layers 310, 310′ comprise copper. Bottom view 420 further shows contact interface 140 of the lid structure 120 provided by contact interfaces 415, 415′. The contact interfaces 415, 415′ are electrically connected to the layer 310 (and/or to layer 310′), e.g., so that an electrical connector can provide a connection between the passive electrical element structure 130, comprising layer 310, and an electrical circuit, e.g. on circuit board 220. FIG. 4 gives an example arrangement of an inductor in one of the passive layers of the multi-purpose shield can lid. The shield above the inductor is also shown. In one example, the inductor can be a one turn inductor, e.g. when the lid structure comprises exclusively the layer 310 or only layer 310 of layers 310 and 310′ is used for implementing the inductor. In another example, the inductor may be a two turn inductor in a multilayer arrangement, e.g. when the lid structure 120 comprises the layer 310 and the layer 310′, wherein the two turn inductor may be provided by the two layers 310 and 310′.

More details and aspects are mentioned in connection with the embodiments described above or below. The embodiments shown in FIG. 4 may comprise one or more optional additional features corresponding to one or more aspects mentioned in connection with the proposed concept or one or more embodiments described above or below (e.g. FIGS. 1 to 3 and 5 to 10).

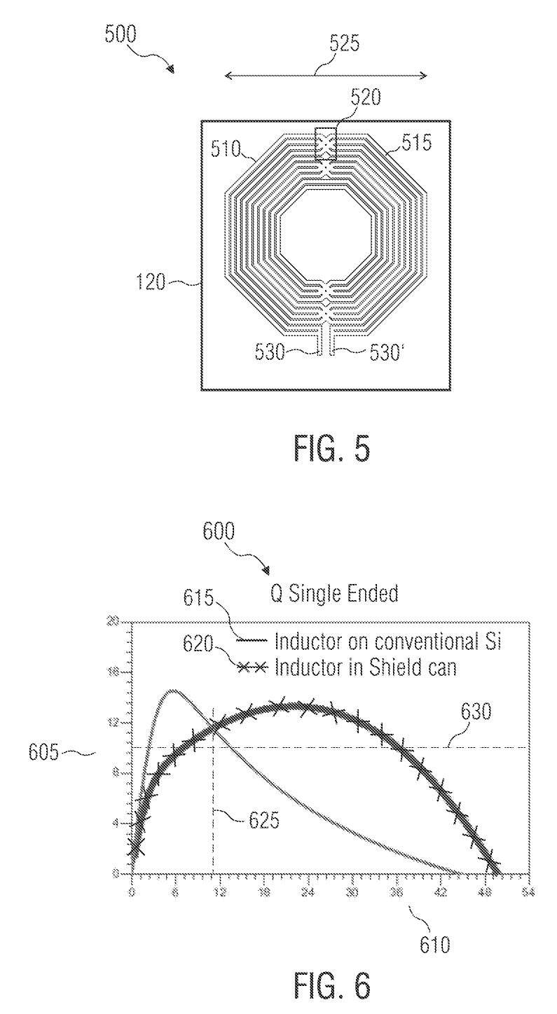

FIG. 5 shows a schematic illustration of an example 500 of a coil 510 embedded in a lid structure 120. The coil 510 comprises electrical traces 515, e.g. provided in a first layer of the lid structure 120. In region 520 at least some of the electrical traces 515 may be lead into another layer of the lid structure 120, e.g. a second layer. A coil side length 525 may be larger than 0.2 mm and/or smaller than 20 cm. The coil 510 may be at least a part of the passive electrical element structure 130 of lid structure 120 and an electrical connection to the coil 510 may be established via contact interfaces 530, 530′ of lid structure 120.

Coil 510 may be a typical DC-DC converter inductor used in the Power management unit of a mobile phone platform as can be integrated into one of the passive layers of the multipurpose shield can lid. Coil side length may be up to a few millimeters. The unique arrangement of inductors in the passive layers of multi-purpose shield can lid may cause two effects. A first effect may be the possibility of space saving: The inductor used for DC-DC converters of power management unit as e.g. shown in FIG. 5 may have an inductance in order of several pH or nH or μH e.g. more than 10 pH (or more than 10 nH, more than 100 nH, more than 10 μH) and/or less than 1 mH (or less than 500 μH, less than 100 μH or less than 10 μH) and would occupy a large space (up to few millimeters) on silicon or PCB. This space may be saved on a silicon substrate or a PCB by integrating the coil or inductor into the lid structure 120 of electromagnetic shielding cap 100.

More details and aspects are mentioned in connection with the embodiments described above or below. The embodiments shown in FIG. 5 may comprise one or more optional additional features corresponding to one or more aspects mentioned in connection with the proposed concept or one or more embodiments described above or below (e.g. FIGS. 1 to 4 and 6 to 10).

FIG. 6 shows a diagram 600 comprising simulated quality factors 605 of coils over a frequency range 610. A first coil 615 is located directly on a silicon substrate and a second coil 620 is located in a lid structure 120 of an electromagnetic shielding cap 100, e.g. located on the silicon substrate. Diagram 600 shows that from a certain frequency 625 on, the quality factor of the second coil is higher than the quality factor of the first coil. An efficiency of the coil may be improved by integrating it into the electromagnetic shielding cap 100 or the lid structure 120, respectively. Further, it can be seen, that the quality factor of the second coil has a higher frequency range with values e.g. higher than a value 630 compared to the first coil. A frequency range with a high quality factor of the coil may be increased by positioning the coil in or on the lid structure 120.

Integration of the coil into the electromagnetic shielding cap 100 may result in a performance improvement: The arrangement far off from the silicon may offer to obtain a broadband Q (quality factor) response as the air in between and the shielding may help to reduce the parasitic coupling to the high loss silicon in the die. It may facilitate to increase an operational frequency of RF circuits. FIG. 6 may show an example of a Single-ended Q response from electromagnetic simulation of e.g. a one turn inductor. The inductor integrated into multi-purpose shield can lid may offer a much broader band than the on-die integration: a Q1 value above, e.g., 4 is maintained up to a frequency of e.g. around 45 GHz, while for the on-die integration, Q1 may drop below 4 at already less than 30 GHz.

More details and aspects are mentioned in connection with the embodiments described above or below. The embodiments shown in FIG. 6 may comprise one or more optional additional features corresponding to one or more aspects mentioned in connection with the proposed concept or one or more embodiments described above or below (e.g. FIGS. 1 to 5 and 7 to 10).

FIG. 7 shows a schematic illustration 700 of a cross section 705 of an electrical system 200. The illustration 700 shows e.g. a top view of the cross section 705. On top of the frame structure 110, the lid structure 120 may be attached to the frame structure 110. For example, the frame structure 110 (e.g., ring of anisotropic conductive film material) may serve as connector to the multi-purpose shielding lid. For example, a ring of an anisotropic conductive film is attached to the top of frame structure 110 between frame structure 110 and lid structure 120.

More details and aspects are mentioned in connection with the embodiments described above or below. The embodiments shown in FIG. 7 may comprise one or more optional additional features corresponding to one or more aspects mentioned in connection with the proposed concept or one or more embodiments described above or below (e.g. FIGS. 1 to 6 and 8 to 10).

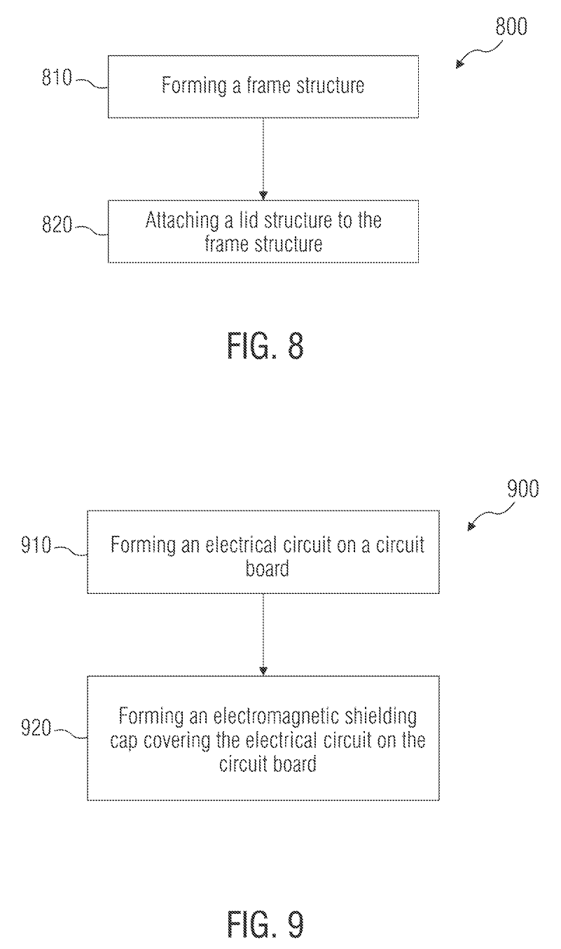

FIG. 8 shows a flow chart of a method 800 for forming an electromagnetic shielding cap. The method 800 comprises forming a frame structure 810 and attaching a lid structure to the frame structure 820. A passive electrical element structure is embedded in the lid structure and the lid structure comprises at least one contact interface for connecting the passive electrical element structure to an electrical circuit to be covered by the electromagnetic shielding cap. An electrical connection may be provided via a connector and optionally the circuit board or alternatively via the frame structure and the circuit board.

For example, the passive electrical element structure may be embedded in the lid structure at the moment of attaching. For example, the passive electrical element structure may be attacked to the lid structure after attaching the lid structure to the frame structure. For example, an electromagnetic shield can may be manufactured to have an insulating layer on an inner side of its lid and a passive electrical element structure may be attached to the insulating layer inside the electromagnetic shield can as the passive electrical element structure. This may make it possible to transform other shielding cans into electromagnetic shielding caps 100.

For example, the method may comprise attaching a lid structure wherein the passive electrical element structure of the lid structure is at least one of a resistor, a capacitor, a coil and an antenna. For example, the method may comprise forming an electrically insulating material around a passive electrical element structure to form a lid structure and attach the lid structure to the frame structure. For example, a passive electrical element may be attached to the lid structure according to the method.

For example, the method may comprise attaching a lid structure wherein the lid structure comprises electrically insulating material embedding the passive electrical element structure, wherein the electrically insulating material is at least one of mold compound, epoxy fiberglass, epoxy fiberglass paper composite, resin, polyester fiberglass, polyimide fiberglass and teflon fiberglass. For example, a passive electrical element structure may be packaged with electrically insulating material according to the method to form a lid structure.

For example, the method may comprise attaching a lid structure wherein the lid structure comprises an electrically conductive shielding structure insulated from the passive electrical element structure, wherein the passive electrical element structure is arranged in one or more layers of the lid structure located closer to the frame structure than one or more layers of the lid structure comprising the electrically conductive shielding structure.

Optionally, attaching the lid structure according to the method may comprise connecting the electrically conductive shielding structure of the lid structure electrically to the frame structure. Connecting may comprise to plug the connector to a contact interface and/or to solder a line of the electrical connector to a contact interface. Connecting may comprise to bond a bonding wire to a bonding pad.

Optionally, attaching the lid structure according to the method may comprise positioning the contact interface of the lid structure on a side of the lid structure facing towards the frame structure. E.g., the lid structure may be attached to the frame structure such that the contact interface faces towards the frame structure.

Optionally, the method may further comprise connecting an electrical connector to the contact interface of the lid structure. For example, according to the method the electrical connector used for connecting may be configured to establish a connection to a terminal of the circuit board, wherein the connector has a height that differs less than 20% from a height of the frame structure.

Optionally, according to the method a frame structure may be formed or used, wherein a height of the frame structure is smaller than 1 cm. The method may comprise forming a frame structure with a height smaller than 1 cm, smaller than 0.5 cm or smaller than 0.3 cm. Optionally, according to the method the frame structure may be made of an electrically conductive material. Optionally, the method may comprise providing separated electrically conductive traces as connections lines in the frame structure.

Optionally, according to the method a side length of a longest side of the lid structure may be smaller than 5 cm. For example, the lid structure may be formed to be smaller than 4 cm or smaller than 2 cm. Optionally, according to the method at least a part of the passive electrical element structure of the lid structure may be formed or made of copper. For example, forming the lid structure may comprise structuring at least one copper plate and forming contact interfaces connected to the structured copper plate.

Optionally, according to the method the contact interface of the lid structure may be positioned in a contact region of the lid structure, wherein the contact region is a region of the lid structure in contact with the frame structure, wherein the frame structure provides an integrated connector configured to establish a connection from the contact interface to a side of the frame structure opposite to the lid structure. The lid structure may be positioned in a way that the contact interface is in contact with the frame structure or the integrated connector of the frame structure.

Optionally, according to the method the lid structure may be attached to the frame structure by at least one of soldering, gluing, clamping, screwing and connecting a pin header. For example, glue may be provided at a contact region of the frame structure and the lid structure before attaching the lid structure to the frame structure. Optionally, the method may comprise positioning an anisotropic conductive film between the frame structure and the lid structure. For example, by using an adhesive anisotropic conductive film the lid structure may be glued to the frame structure while at the same time providing an electrical connection between the lid structure and the frame structure.

More details and aspects are mentioned in connection with the embodiments described above or below. The embodiments shown in FIG. 8 may comprise one or more optional additional features corresponding to one or more aspects mentioned in connection with the proposed concept or one or more embodiments described above or below (e.g. FIGS. 1 to 7 and 9 to 10).

FIG. 9 shows a schematic illustration of a flow chart of a method 900 for forming an electrical system. Method 900 comprises forming an electrical circuit on a circuit board 910 and forming an electromagnetic shielding cap covering the electrical circuit on the circuit board 920. Forming the electromagnetic shielding cap comprises providing a frame structure and providing a lid structure embedding a passive electrical element structure, and attaching the lid structure to the frame structure, wherein the lid structure comprises at least one contact interface for connecting the passive electrical element structure to an electrical circuit to be covered by the electromagnetic shielding cap.

Optionally, the method may comprise providing an electrical connector providing an electrical connection between the contact interface of the lid structure and the electrical circuit on the circuit board. The method may comprise connecting the contact interface electrically to the passive electrical element structure within the lid structure. For example, the electrical connector may be connected to the circuit board before attaching the lid structure to the frame structure. For example, the electrical connector may be connected to the contact interface of the lid structure before attaching the lid structure to the frame structure.

Optionally, the method may comprise connecting the frame structure electrically to a reference voltage terminal of the circuit board, e.g. to a ground terminal. For example, the electrical connection could be provided via a mechanical attachment structure used to mount the electromagnetic shielding cap to the circuit board. The mechanical attachment structure may be a plug connection with metal plugs, for example. Alternatively, the electrical connection could be provided by an electrically conductive connection wire reaching from the frame structure to the reference voltage terminal.

Optionally, according to the method the electrical circuit on the circuit board may be at least one of a transmitter circuit, a receiver circuit, a transceiver circuit and a voltage converter circuit. For example, the electromagnetic shielding cap could be used to cover at least a part of a transmitter circuit, a receiver circuit, a transceiver circuit or a voltage converter circuit. For example, a part of a respective circuit sensitive to interfering electromagnetic radiation could be shielded by the electromagnetic shielding cap while a remaining part could remain uncovered.

Optionally, according to the method the electrical circuit on the circuit board may be a DC-DC converter circuit and the passive electrical element structure of the lid structure is a coil for the DC-DC converter circuit. For example, a semiconductor circuit may be formed on the circuit board. The semiconductor circuit may need a coil element to provide functionality of a DC-DC converter. The needed coil may be formed in the lid structure and connected to the semiconductor circuit via a connector when covering the semiconductor circuit with the electromagnetic shielding cap.

More details and aspects are mentioned in connection with the embodiments described above or below. The embodiments shown in FIG. 9 may comprise one or more optional additional features corresponding to one or more aspects mentioned in connection with the proposed concept or one or more embodiments described above or below (e.g. FIG. 1 to 8 or 10).

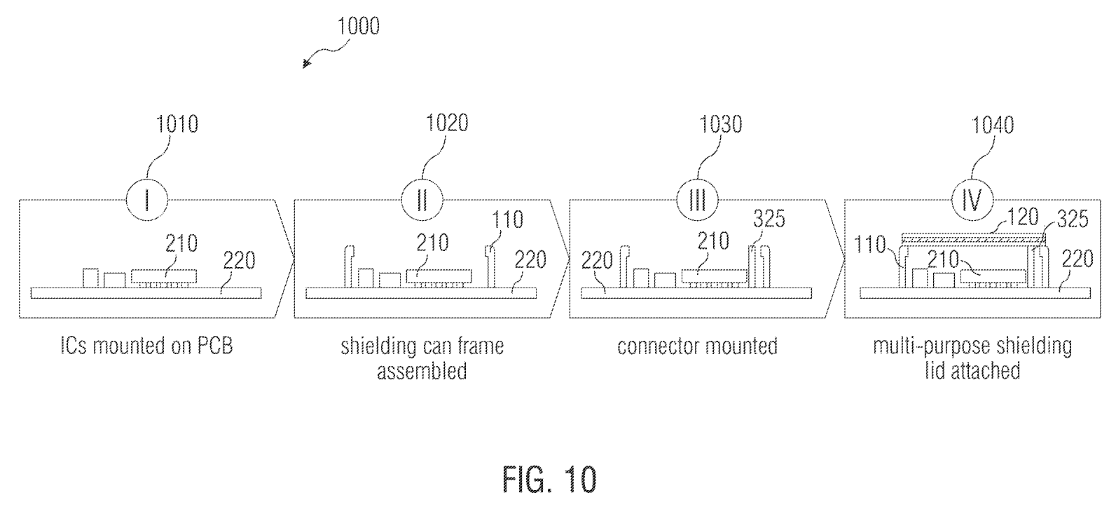

FIG. 10 shows a schematic illustration of a method 1000 for forming an electrical system. The method 1000 comprises attaching or forming 1010 an electrical circuit 210 on a circuit board 220, the electrical circuit 210 comprising a terminal for an electrical connector (not shown). The method 1000 comprises attaching 1020 a frame structure 110 to the circuit board 220 around at least a part of the electrical circuit 210. The method 1000 comprises connecting 1030 an electrical connector 325 to the terminal of the electrical circuit 210. The method 1000 comprises attaching 1040 a lid structure 120 onto the frame structure 110 and electrically connecting the lid structure at least to one of the frame structure 110 and the electrical connector 325. The steps 1020 and 1030 may be performed in another order, e.g. the electrical connector may be attached to the circuit board before attaching the frame structure. Alternatively, it may be possible to first connect the electrical connector to the lid structure and to attach the lid structure to the frame structure and then attach the electromagnetic shielding cap 100 together with the electrical connector to the circuit board.

FIG. 10 provides an exemplary assembly flow for manufacturing an electromagnetic shielding structure on a circuit board. ICs may be placed on a PCB. The PCB and IC design may account for passives being moved to the multi-purpose shield can lid. A shielding can frame may be placed on the PCB, and connected by clamping or in a later process step by soldering. A connector may be placed on the PCB.

Assembly steps 1010, 1020 and 1030 can be interchanged or combined if beneficial for the process flow. Alternatively, the connector can first be attached to the multi-purpose shielding lid, and connected to the PCB only at/before step 1040. Instead of connecting to the PCB, the connector can also connect directly to ICs. Options for the connector include anisotropic conductive films. A suitable connector might also replace one or more of the shielding can frame walls. A Multi-purpose shielding lid may be attached to the shield frame. Bonding with the connector may happen by attaching or might require a separate process step before. Options for attaching the lid to the frame include: soldering, gluing, clamping, screwing, fitting pin headers, etc.

More details and aspects are mentioned in connection with the embodiments described above or below. The embodiments shown in FIG. 10 may comprise one or more optional additional features corresponding to one or more aspects mentioned in connection with the proposed concept or one or more embodiments described above or below (e.g. FIGS. 1 to 9).

Further examples relate to a transceiver circuit comprising an electrical circuit on a circuit board and an electromagnetic shielding cap covering the electrical circuit on the circuit board. The electromagnetic shielding cap may comprise a frame structure and a lid structure embedding a passive electrical element structure, wherein the lid structure may be attached to the frame structure. The lid structure may comprise at least one contact interface for connecting the passive electrical element structure to an electrical circuit to be shielded by the electromagnetic shielding cap. More details and aspects are mentioned in connection with the embodiments described above or below.

Further examples relate to a mobile device comprising an electrical circuit on a circuit board and an electromagnetic shielding cap covering the electrical circuit on the circuit board. The electromagnetic shielding cap may comprise a frame structure and a lid structure embedding a passive electrical element structure, wherein the lid structure may be attached to the frame structure, wherein the lid structure may comprise at least one contact interface for connecting the passive electrical element structure to an electrical circuit to be shielded by the electromagnetic shielding cap. More details and aspects are mentioned in connection with the embodiments described above or below.

Examples relate to a multi-purpose shield can lid. There exist multiple possibilities for flexible or rigid 3D connection between lid structure and PCBs or from ICs to PCB. With the electromagnetic shielding structure 100 better performance due to reduced parasitic couplings, area savings on die and/or package and/or PCB may be achieved.

In general, the multi-purpose shielding lid may integrate passives to save PCB area and may reduce electromagnetic interference by distance increase. RF (radio frequency) and power management circuits may comprise passive elements which are sensitive to electromagnetic interference. Ideal placement in limited space may be a challenge. Moving passives into the multi-purpose shield can lid, e.g. the lid structure 120, may save space on a die and/or package and/or PCB and may increase design flexibility.

It is proposed to replace a conventional lid of a shielding can by a single or multilayer circuit carrier/substrate (e.g., MIS=Molded Interconnect Substrate) containing structures for the shielding purpose along with passives, and possible implementations of, e.g., inductors.

A multi-purpose shield can lid may increase integration density by moving circuit elements to previously unused space. This may save area on a die and/or package and/or PCB and may improve performance due to a possibility reduced parasitic coupling. It may be of particular interest in RF and mm wave applications. Some examples for passives which can be integrated into multi-purpose shield can lid are: inductors, resistors, antenna structures, caps (e.g., by embedding integrated passive devices or SMDs). Inductors may be suitable for integration into a multi-purpose shield can lid. A performance advantage of the integration of a coil into multi-purpose shield can lid may arise compared to the on-die solution with a coil on the die.

A passive electrical element structure in a shielding cap may be detected by X-ray. The electromagnetic shielding cap may be provided for shielding chipsets and/or wireless devices.

Further examples of concepts for shielding an electrical circuit are provided.

Example 1 shows an electromagnetic shielding cap for shielding an electrical circuit on a circuit board, the electromagnetic shielding cap comprising a frame structure; and lid structure comprising a passive electrical element structure, wherein the lid structure is attached to the frame structure, wherein the lid structure comprises at least one contact interface for connecting the passive electrical element structure to an electrical circuit to be shielded by the electromagnetic shielding cap.

Example 2 shows the electromagnetic shielding cap according to example 1, wherein the passive electrical element structure of the lid structure comprises at least one of a resistor, a capacitor, a coil and an antenna.

Example 3 shows the electromagnetic shielding cap according to one of examples 1 or 2, wherein the lid structure comprises electrically insulating material embedding the passive electrical element structure, wherein the electrically insulating material is at least one of molding compound, epoxy fiberglass, epoxy fiberglass paper composite, resin, polyester fiberglass, polyimide fiberglass and teflon fiberglass.

Example 4 shows the electromagnetic shielding cap according to one of examples 1 to 3, wherein the lid structure comprises an electrically conductive shielding structure insulated from the passive electrical element structure, wherein the passive electrical element structure is arranged in one or more layers of the lid structure located closer to the frame structure than one or more layers of the lid structure comprising the electrically conductive shielding structure.

Example 5 shows the electromagnetic shielding cap according to example 4, wherein the electrically conductive shielding structure of the lid structure is electrically connected to the frame structure.

Example 6 shows the electromagnetic shielding cap according to one of examples 1 to 5, wherein the frame structure is electrically conductive.

Example 7 shows the electromagnetic shielding cap according to one of examples 1 to 6, wherein the contact interface of the lid structure is positioned on a side of the lid structure facing towards the frame structure.

Example 8 shows the electromagnetic shielding cap according to one of examples 1 to 7, wherein an electrical connector is connected to the contact interface of the lid structure.

Example 9 shows the electromagnetic shielding cap according to example 8, wherein the electrical connector is configured to establish an electrical connection between the contact interface of the lid structure and a contact interface of the circuit board or a contact interface of the electrical circuit.

Example 10 shows the electromagnetic shielding cap according to example 8 or 9, wherein a height of the electrical connector differs from a height of the frame structure by less than 20% of the height of the frame structure.

Example 11 shows the electromagnetic shielding cap according to one of examples 1 to 7, wherein the contact interface of the lid structure is positioned in a contact region of the lid structure, wherein the contact region is a region of the lid structure in contact with the frame structure, wherein the frame structure comprises at least one conductive trace connected to the contact interface of the lid structure and extending from the contact region to a side of the frame structure opposite to the lid structure.

Example 12 shows the electromagnetic shielding cap according to one of examples 1 to 11, wherein the lid structure is soldered, glued, clamped, screwed or connected by a pin header to the frame structure.

Example 13 shows the electromagnetic shielding cap according to one of examples 1 to 12, wherein an anisotropic conductive film is located between the frame structure and the lid structure.

Example 14 shows the electromagnetic shielding cap according to one of examples 1 to 13, wherein a side length of a longest side of the lid structure is smaller than 5 cm.

Example 15 shows the electromagnetic shielding cap according to one of examples 1 to 14, wherein a height of the frame structure is smaller than 1 cm.

Example 16 shows the electromagnetic shielding cap according to one of examples 1 to 15, wherein at least a part of the passive electrical element structure of the lid structure comprises copper.

Example 17 shows the electromagnetic shielding cap according to one of examples 1 to 16, wherein the lid structure comprises a plurality of lateral wiring layers and a plurality of vertical wiring layers.

Example 18 shows an electrical system comprising an electrical circuit on a circuit board; and an electromagnetic shielding cap shielding the electrical circuit on the circuit board, wherein the electromagnetic shielding cap comprises a frame structure and a lid structure comprising a passive electrical element structure, wherein the lid structure is attached to the frame structure, wherein the lid structure comprises at least one contact interface for connecting the passive electrical element structure to the electrical circuit.

Example 19 shows the electrical system according to example 18, further comprising an electrical connector providing an electrical connection between the contact interface of the lid structure and a contact interface of the circuit board or a contact interface of the electrical circuit on the circuit board.

Example 20 shows the electrical system according to example 18 or 19, wherein the frame structure is electrically connected to a reference voltage terminal of the circuit board.

Example 21 shows The electrical system according to one of examples 18 to 20, wherein the electrical circuit on the circuit board is at least one of a transmitter circuit, a receiver circuit, a transceiver circuit and a voltage converter circuit.

Example 22 shows the electrical system according to one of examples 18 to 21, wherein the electrical circuit on the circuit board is a DC-DC converter circuit and the passive electrical element structure of the lid structure is a coil for the DC-DC converter circuit.

Example 23 shows the electrical system according to one of examples 18 to 22, wherein the electrical circuit on the circuit board is a semiconductor circuit.

Example 24 shows a transceiver circuit comprising an electrical circuit on a circuit board; and an electromagnetic shielding cap shielding the electrical circuit on the circuit board, wherein the electromagnetic shielding cap comprises a frame structure and a lid structure comprising a passive electrical element structure, wherein the lid structure is attached to the frame structure, wherein the lid structure comprises at least one contact interface for connecting the passive electrical element structure to the electrical circuit.

Example 25 shows a mobile device comprising an electrical circuit on a circuit board; and an electromagnetic shielding cap shielding the electrical circuit on the circuit board, wherein the electromagnetic shielding cap comprises a frame structure and a lid structure comprising a passive electrical element structure, wherein the lid structure is attached to the frame structure, wherein the lid structure comprises at least one contact interface for connecting the passive electrical element structure to the electrical circuit.

Example 26 shows a method for forming an electromagnetic shielding cap, the method comprising providing a frame structure; and attaching a lid structure to the frame structure, wherein the lid structure comprises a passive electrical element structure and the lid structure comprises at least one contact interface for connecting the passive electrical element structure to an electrical circuit to be shielded by the electromagnetic shielding cap.

Example 27 shows the method according to example 26, wherein the passive electrical element structure of the lid structure is at least one of a resistor, a capacitor, a coil and an antenna.

Example 28 shows the method according to example 26 or 27, wherein the lid structure comprises electrically insulating material embedding the passive electrical element structure, wherein the electrically insulating material is at least one of molding compound, epoxy fiberglass, epoxy fiberglass paper composite, resin, polyester fiberglass, polyimide fiberglass and teflon fiberglass.

Example 29 shows the method according to one of examples 26 to 28, wherein the lid structure comprises an electrically conductive shielding structure insulated from the passive electrical element structure, wherein the passive electrical element structure is arranged in one or more layers of the lid structure located closer to the frame structure than one or more layers of the lid structure comprising the electrically conductive shielding structure.

Example 30 shows the method according to example 29, wherein attaching the lid structure comprises electrically connecting the electrically conductive shielding structure of the lid structure to the frame structure.

Example 31 shows the method according to one of examples 26 to 30, wherein attaching the lid structure comprises positioning the contact interface of the lid structure on a side of the lid structure facing towards the frame structure.

Example 32 shows the method according to one of examples 26 to 31, further comprising connecting an electrical connector to the contact interface of the lid structure.

Example 33 shows the method according to example 32, wherein the electrical connector is configured to establish a connection to a terminal of the circuit board.

Example 34 shows the method according to one of examples 32 or 33, wherein a height of the electrical connector differs from a height of the frame structure by less than 20% of the height of the frame structure.

Example 35 shows the method according to one of examples 26 to 34, wherein attaching comprises positioning the contact interface of the lid structure in a contact region of the lid structure, wherein the contact region is a region of the lid structure in contact with the frame structure, wherein the frame structure provides an integrated connector configured to establish a connection from the contact interface to a side of the frame structure opposite to the lid structure.

Example 36 shows the method according to one of examples 26 to 35, wherein attaching the lid structure to the frame structure comprises at least one of soldering, gluing, clamping, screwing and connecting a pin header.

Example 37 shows the method according to one of examples 26 to 36, further comprising positioning an anisotropic conductive film between the frame structure and the lid structure.

Example 38 shows the method according to one of examples 26 to 37, wherein the frame structure is electrically conductive.

Example 39 shows the method according to one of examples 26 to 38, wherein a side length of a longest side of the lid structure is smaller than 5 cm.

Example 40 shows the method according to one of examples 26 to 39, wherein a height of the frame structure is smaller than 1 cm.

Example 41 shows the method according to one of examples 26 to 40, wherein at least a part of the passive electrical element structure of the lid structure comprises copper.

Example 42 shows the method according to one of examples 26 to 41, wherein the lid structure comprises a plurality of lateral wiring layers and a plurality of vertical wiring layers.

Example 43 shows a method for forming an electrical system, the method comprising forming an electrical circuit on a circuit board; and forming an electromagnetic shielding cap shielding the electrical circuit on the circuit board, wherein forming the electromagnetic shielding cap comprises providing a frame structure and providing a lid structure embedding a passive electrical element structure, and attaching the lid structure to the frame structure, wherein the lid structure comprises at least one contact interface for connecting the passive electrical element structure to the electrical circuit.

Example 44 shows the method according to example 43, further comprising providing an electrical connector and providing an electrical connection between the contact interface of the lid structure and the electrical circuit on the circuit board by the electrical connector.

Example 45 shows the method according to 43 or 44, wherein the frame structure is electrically connected to a reference voltage terminal of the circuit board.

Example 46 shows the method according to one of examples 43 to 45, wherein the electrical circuit on the circuit board is at least one of a transmitter circuit, a receiver circuit, a transceiver circuit and a voltage converter circuit.

Example 47 shows the method according to example 46, wherein the electrical circuit on the circuit board is a DC-DC converter circuit and the passive electrical element structure of the lid structure is a coil for the DC-DC converter circuit.

Example 48 shows the method according to one of examples 43 to 47, wherein the electrical circuit on the circuit board is a semiconductor circuit.

Example 49 shows a non-transitory machine readable storage medium including program code, when executed, to cause a programmable processor to perform the method of one of examples 26 to 48.

The aspects and features mentioned and described together with one or more of the previously detailed examples and figures, may as well be combined with one or more of the other examples in order to replace a like feature of the other example or in order to additionally introduce the feature to the other example.

Examples may further be or relate to a computer program having a program code for performing one or more of the above methods, when the computer program is executed on a computer or processor. Steps, operations or processes of various above-described methods may be performed by programmed computers or processors. Examples may also cover program storage devices such as digital data storage media, which are machine, processor or computer readable and encode machine-executable, processor-executable or computer-executable programs of instructions. The instructions perform or cause performing some or all of the acts of the above-described methods. The program storage devices may comprise or be, for instance, digital memories, magnetic storage media such as magnetic disks and magnetic tapes, hard drives, or optically readable digital data storage media. Further examples may also cover computers, processors or control units programmed to perform the acts of the above-described methods or (field) programmable logic arrays ((F)PLAs) or (field) programmable gate arrays ((F)PGAs), programmed to perform the acts of the above-described methods.

The description and drawings merely illustrate the principles of the disclosure. Furthermore, all examples recited herein are principally intended expressly to be only for pedagogical purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

A functional block denoted as “means for . . . ” performing a certain function may refer to a circuit that is configured to perform a certain function. Hence, a “means for s.th.” may be implemented as a “means configured to or suited for s.th.”, such as a device or a circuit configured to or suited for the respective task.

Functions of various elements shown in the figures, including any functional blocks labeled as “means”, “means for providing a signal”, “means for generating a signal.”, etc., may be implemented in the form of dedicated hardware, such as “a signal provider”, “a signal processing unit”, “a processor”, “a controller”, etc. as well as hardware capable of executing software in association with appropriate software. When provided by a processor, the functions may be provided by a single dedicated processor, by a single shared processor, or by a plurality of individual processors, some of which or all of which may be shared. However, the term “processor” or “controller” is by far not limited to hardware exclusively capable of executing software, but may include digital signal processor (DSP) hardware, network processor, application specific integrated circuit (ASIC), field programmable gate array (FPGA), read only memory (ROM) for storing software, random access memory (RAM), and non-volatile storage. Other hardware, conventional and/or custom, may also be included.

A block diagram may, for instance, illustrate a high-level circuit diagram implementing the principles of the disclosure. Similarly, a flow chart, a flow diagram, a state transition diagram, a pseudo code, and the like may represent various processes, operations or steps, which may, for instance, be substantially represented in computer readable medium and so executed by a computer or processor, whether or not such computer or processor is explicitly shown. Methods disclosed in the specification or in the claims may be implemented by a device having means for performing each of the respective acts of these methods.

It is to be understood that the disclosure of multiple acts, processes, operations, steps or functions disclosed in the specification or claims may not be construed as to be within the specific order, unless explicitly or implicitly stated otherwise, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

Furthermore, the following claims are hereby incorporated into the detailed description, where each claim may stand on its own as a separate example. While each claim may stand on its own as a separate example, it is to be noted that—although a dependent claim may refer in the claims to a specific combination with one or more other claims—other examples may also include a combination of the dependent claim with the subject matter of each other dependent or independent claim. Such combinations are explicitly proposed herein unless it is stated that a specific combination is not intended. Furthermore, it is intended to include also features of a claim to any other independent claim even if this claim is not directly made dependent to the independent claim.

What is claimed is:

1. An electromagnetic shielding cap for shielding an electrical circuit on a circuit board, the electromagnetic shielding cap comprising:
A frame structure; and
A lid structure comprising a passive electrical element structure, wherein the lid structure is attached to the frame structure, wherein the lid structure comprises at least one contact interface for connecting the passive electrical element structure to an electrical circuit to be shielded by the electromagnetic shielding cap.

2. The electromagnetic shielding cap according to claim 1,
wherein the passive electrical element structure of the lid structure comprises at least one of a resistor, a capacitor, a coil and an antenna.

3. The electromagnetic shielding cap according to claim 1,
wherein the lid structure comprises electrically insulating material embedding the passive electrical element structure, wherein the electrically insulating material is at least one of molding compound, epoxy fiberglass, epoxy fiberglass paper composite, resin, polyester fiberglass, polyimide fiberglass and teflon fiberglass.

4. The electromagnetic shielding cap according to claim 1,
wherein the lid structure comprises an electrically conductive shielding structure insulated from the passive electrical element structure, wherein the passive electrical element structure is arranged in one or more layers of the lid structure located closer to the frame structure than one or more layers of the lid structure comprising the electrically conductive shielding structure.

5. The electromagnetic shielding cap according to claim 4,
wherein the electrically conductive shielding structure of the lid structure is electrically connected to the frame structure.

6. The electromagnetic shielding cap according to claim 1,
wherein the frame structure is electrically conductive.

7. The electromagnetic shielding cap according to claim 1,
wherein the contact interface of the lid structure is positioned on a side of the lid structure facing towards the frame structure.

8. The electromagnetic shielding cap according to claim 1,
wherein an electrical connector is connected to the contact interface of the lid structure.

9. The electromagnetic shielding cap according to claim 8,
wherein the electrical connector is configured to establish an electrical connection between the contact interface of the lid structure and a contact interface of the circuit board or a contact interface of the electrical circuit.

10. The electromagnetic shielding cap according to claim 8,
wherein a height of the electrical connector differs from a height of the frame structure by less than 20% of the height of the frame structure.

11. The electromagnetic shielding cap according to claim 1,
wherein the contact interface of the lid structure is positioned in a contact region of the lid structure, wherein the contact region is a region of the lid structure in contact with the frame structure, wherein the frame structure comprises at least one conductive trace connected to the contact interface of the lid structure and extending from the contact region to a side of the frame structure opposite to the lid structure.

12. The electromagnetic shielding cap according to claim 1,
wherein the lid structure is soldered, glued, clamped, screwed or connected by a pin header to the frame structure.

13. The electromagnetic shielding cap according to claim 1,
wherein an anisotropic conductive film is located between the frame structure and the lid structure.

14. The electromagnetic shielding cap according to claim 1,
wherein a side length of a longest side of the lid structure is smaller than 5 cm.

15. The electromagnetic shielding cap according to claim 1,
wherein a height of the frame structure is smaller than 1 cm.

16. The electromagnetic shielding cap according to claim 1,
wherein at least a part of the passive electrical element structure of the lid structure comprises copper.

17. The electromagnetic shielding cap according to claim 1,
wherein the lid structure comprises a plurality of lateral wiring layers and a plurality of vertical wiring layers.

18. Electrical system comprising:
An electrical circuit on a circuit board; and
An electromagnetic shielding cap shielding the electrical circuit on the circuit board, wherein the electromagnetic shielding cap comprises a frame structure and a lid structure comprising a passive electrical element structure, wherein the lid structure is attached to the frame structure, wherein the lid structure comprises at least one contact interface for connecting the passive electrical element structure to the electrical circuit.

19. The electrical system according to claim 18, further comprising
an electrical connector providing an electrical connection between the contact interface of the lid structure and a contact interface of the circuit board or a contact interface of the electrical circuit on the circuit board.

20. The electrical system according to claim 18,
wherein the electrical circuit on the circuit board is at least one of a transmitter circuit, a receiver circuit, a transceiver circuit and a voltage converter circuit.

21. The electrical system according to claim 18,
wherein the electrical circuit on the circuit board is a DC-DC converter circuit and the passive electrical element structure of the lid structure is a coil for the DC-DC converter circuit.

22. A method for forming an electromagnetic shielding cap, the method comprising:
Providing a frame structure; and
Attaching a lid structure to the frame structure, wherein the lid structure comprises a passive electrical element structure and the lid structure comprises at least one contact interface for connecting the passive electrical element structure to an electrical circuit to be shielded by the electromagnetic shielding cap.

23. The method according to claim 22, wherein the passive electrical element structure of the lid structure is at least one of a resistor, a capacitor, a coil and an antenna.

24. A method for forming an electrical system, the method comprising:
Forming an electrical circuit on a circuit board; and
Forming an electromagnetic shielding cap shielding the electrical circuit on the circuit board, wherein forming the electromagnetic shielding cap comprises providing a frame structure and providing a lid structure embedding a passive electrical element structure, and attaching the lid structure to the frame structure, wherein the lid structure comprises at least one contact interface for connecting the passive electrical element structure to the electrical circuit.

25. The method according to claim 24, further comprising
Providing an electrical connector and providing an electrical connection between the contact interface of the lid structure and the electrical circuit on the circuit board by the electrical connector.
